(19) United States
(12) Patent Application Publication
(10) Pub. No.: US 2012/0055706 A1
(43) Pub. Date: Mar. 8, 2012

(54) PRINTED CIRCUIT BOARD AND METHOD OF MANUFACTURING THE SAME

(75) Inventor: Jee Soo MOK, Gyunggi-do (KR)

(73) Assignee: SAMSUNG ELECTRO-MECHANICS CO., LTD., Gyunggi-do (KR)

(21) Appl. No.: 13/080,134

(22) Filed: Apr. 5, 2011

(30) Foreign Application Priority Data
Sep. 3, 2010 (KR) 10-2010-0086555

(51) Int. Cl. H05K 1/16; H01G 7/00

(52) U.S. Cl. 174/260; 29/25.41

(57) ABSTRACT

Disclosed herein is a printed circuit board, including: a core layer having a first circuit layer formed on an outer surface thereof; and a capacitor layer stacked on the core layer to be electrically connected to the first circuit layer, having an inner insulating layer therebetween, and including a plurality of conductive projection parts formed on the opposite surfaces of an upper electrode layer and a lower electrode layer and a dielectric layer formed between the upper electrode layer and the lower electrode layer.

### CROSS REFERENCE TO RELATED APPLICATION

This application claims the benefit of Korean Patent Application No. 10-2010-0086555, filed on Sep. 3, 2010, entitled “Printed Circuit Board And Manufacturing Method Thereof” which is hereby incorporated by reference in its entirety into this application.

### BACKGROUND OF THE INVENTION

1. Technical Field

The present invention relates to a printed circuit board and a method of manufacturing the same.

2. Description of the Related Art

A printed circuit board is a component transferring a signal, supplying power, or the like, through an electrical connection between electronic components. The printed circuit board has been developed to accept fineness of an active device and a semiconductor component and lightness and slimness of an electronic product, rather than be independently developed.

The trend in lightness and slimness of the electronic component has been applied to a passive device in the same manner. However, there is a limit in the lightness and slimness of the passive device and there is also a problem in using space. In order to solve these problems, a method of replacing a separate capacitor device using a new material or a process has been developed. This is a method of embedding a capacitor in a printed circuit board itself when manufacturing the circuit board.

As a method of manufacturing a printed circuit board embedded with a capacitor, there is a method of manufacturing a printed circuit board embedded with a poly thick film type capacitor. This method applies and dries a poly capacitor paste to an inner layer of the printed circuit board and then prints and dries a copper paste so as to form an electrode, thereby manufacturing an embedded type capacitor.

As another method, there is a method of implementing an embedded discrete type capacitor by coating a ceramic filled photo-dielectric capacitor on the printed circuit board, which was disclosed by Motorola, Inc., in the USA. This method etches the photo-dielectric resin containing ceramic powders, thereby implementing discrete type capacitor.

Finally, there is a method of implementing a capacitor by inserting a separate dielectric layer into an inner layer of a printed circuit board so as to replace a decoupling capacitor mounted on a surface of a printed circuit board, of which relevant patent technologies are owned by Sanmina-SCI Corp., in the USA. This method inserts a dielectric layer, a power electrode layer, and a ground electrode layer into an inner layer of the printed circuit board, thereby implementing a power distributed decoupling capacitor. In order to do so, a surface should be made flat by coating a portion of an inner core board on which a circuit is formed with an insulating ink, such that a polishing process is required. However, a deviation in thickness is generated due to unevenness in polishing, such that characteristics of the capacitor are not constant.

The printed circuit board manufactured as described above uses the circuit layer and the insulating layer configuring the printed circuit board as an electrode layer and a dielectric layer, thereby having various limitations in forming a high-capacitance capacitor. For example, area of the electrode layer is widened to occupy a large area or an expensive dielectric material is inserted into the printed circuit board which increases manufacturing cost.

### SUMMARY OF THE INVENTION

The present invention has been made in an effort to provide a printed circuit board, in which conductive projection parts are formed on the opposite surfaces of two electrode layers formed, having a dielectric layer therebetween, to widen area of a capacitor and reduce a distance between the electrode layers, thereby having an embedded high-capacitance capacitor.

The present invention has been also made in an effort to provide a method of manufacturing an embedded capacitor forming the conductive projection parts using a conductive paste or having a shape in which the electrode layers and the conducive projection parts are integrally formed using a plating scheme.

A printed circuit board according to a preferred embodiment of the present invention includes: a core layer having a first circuit layer formed on an outer surface thereof; and a capacitor layer stacked on the core layer to be electrically connected to the first circuit layer, having an inner insulating layer therebetween, and including a plurality of conductive projection parts formed on the opposite surfaces of an upper electrode layer and a lower electrode layer and a dielectric layer formed between the upper electrode layer and the lower electrode layer.

The printed circuit board further includes a second circuit layer formed on the dielectric layer and formed on the same plane as any one or more of the upper electrode layer and the lower electrode layer.

The printed circuit board further includes a build-up layer stacked on the capacitor layer.

The printed circuit board further includes a protective layer formed on the capacitor layer.

Any one or more of the conductive projection parts formed on the upper electrode layer and the lower electrode layer is made of a conductive paste.

Any one or more of the conductive projection parts formed on the upper electrode layer and the lower electrode layer is a plating layer formed integrally with the upper electrode layer or the lower electrode layer.

A method of manufacturing a printed circuit board according to a preferred embodiment of the present invention includes: forming a core layer having a first circuit layer formed on an outer surface thereof; forming a capacitor layer including a plurality of conductive projection parts formed on the opposite surfaces of an upper electrode layer and a lower electrode layer and a dielectric layer formed between the upper electrode layer and the lower electrode layer; and stacking the capacitor layer on the core layer so that the lower electrode layer is connected to the first circuit layer, having an inner insulating layer therebetween.

The forming the capacitor layer further includes forming a second circuit layer disposed on the same plane as the upper electrode layer or the lower electrode layer.

The method of manufacturing a printed circuit board further includes stacking a build-up layer on the capacitor layer.

The method of manufacturing a printed circuit board further includes forming a protective layer on a top side of the capacitor layer.

The forming the capacitor layer includes: forming conductive projection parts made of a conductive paste on any one of the upper electrode layer and the lower electrode layer; stacking a dielectric layer on the upper electrode layer or the lower electrode layer so as to cover the conductive projection parts; forming a plurality of blind via holes in a thickness direction from a top surface of the dielectric layer so as to be positioned between the conductive projection parts; and forming a plating layer on a top surface of the dielectric layer so that the blind via holes are filled.

The forming the capacitor layer includes: forming conductive projection parts made of a conductive paste on the upper electrode layer and the lower electrode layer; and bonding the dielectric layer, the upper electrode layer, and the lower electrode layer so that the conductive projection parts are disposed on the opposite surfaces of the upper electrode layer and the lower electrode layer, having the dielectric layer therebetween.

The forming the capacitor layer includes: forming a plurality of blind via holes on both surfaces of the dielectric layer; and forming a plating layer on both surfaces of the dielectric layer so that the blind via holes are filled.

The forming the capacitor layer includes: forming a plurality of blind via holes on both surfaces of the dielectric layer having copper foils formed on both surfaces thereof; and forming a plating layer on both surfaces of the dielectric layer so that the blind via holes are filled.

### BRIEF DESCRIPTION OF THE DRAWINGS

FIG. 1 is a cross-sectional view schematically showing a printed circuit board according to a preferred embodiment of the present invention;

FIGS. 2 and 3 are cross-sectional views schematically showing a modified example of the printed circuit board of FIG. 1; and

FIGS. 4 to 21 are cross-sectional views schematically showing a manufacturing process of the printed circuit board of FIGS. 1 to 3.

### DESCRIPTION OF THE PREFERRED EMBODIMENTS

Various objects, advantages and features of the invention will become apparent from the following description of embodiments with reference to the accompanying drawings.

The terms and words used in the present specification and claims should not be interpreted as being limited to typical meanings or dictionary definitions, but should be interpreted as having meanings and concepts relevant to the technical scope of the present invention based on the rule according to which an inventor can appropriately define the concept of the term to describe most appropriately the best method he or she knows for carrying out the invention.

The above and other objects, features and advantages of the present invention will be more clearly understood from the following detailed description taken in conjunction with the accompanying drawings. In the specification, in adding reference numerals to components throughout the drawings, it is to be noted that like reference numerals designate like components even though components are shown in different drawings. Further, when it is determined that the detailed description of the known art related to the present invention may obscure the gist of the present invention, the detailed description thereof will be omitted.

Hereinafter, preferred embodiments of the present invention will be described in detail with reference to the accompanying drawings.

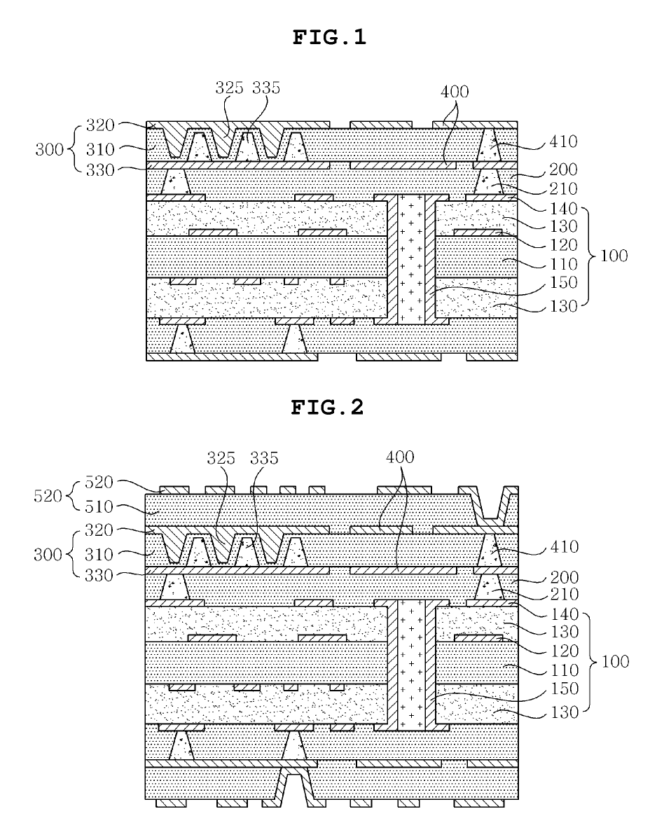

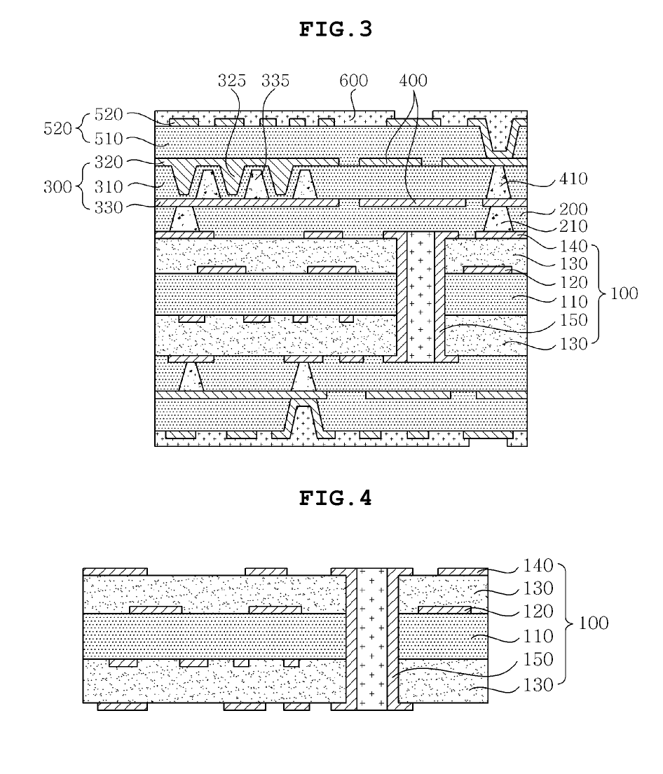

FIG. 1 is a cross-sectional view schematically showing a printed circuit board according to a preferred embodiment of the present invention, and FIGS. 2 and 3are cross-sectional views schematically showing a modified example of the printed circuit board of FIG. 1. Hereinafter, a printed circuit board according to the present embodiment will be described with reference to the figures.

As shown in FIG. 1, the printed circuit board according to the present invention includes a core layer 100 and a capacitor layer 300 to have a multilayer structure. The embedded capacitor layer 300 includes an upper electrode layer 320 and a lower electrode layer 330, having a dielectric layer 310 therebetween, wherein the upper electrode layer 320 and the lower electrode layer 330 are formed with a plurality of conductive projection parts 325 and 335 formed on the opposite surfaces thereof.

The core layer 100 is defined as an inner layer that is positioned in the central portion of the inside of the printed circuit board to be the base for manufacturing a multilayer printed circuit board. The core layer 100 may use an insulating layer made of phenol resin, epoxy resin, imide resin or the like, a prepreg that is an insulating layer including a reinforcing material, or a metal member.

In addition, a first circuit layer 140 is formed on an outer surface of the core layer 100. At this time, the first circuit layer 140, which configures an inner circuit layer of the multilayer printed circuit board, is described as a ‘first circuit layer’ so as to be distinguished from other circuit layers formed on the outer side of the core layer 100.

The printed circuit board of FIG. 1 describes the core layer 100 including a prepreg 110 having a circuit layers 120 formed on both surfaces thereof, an insulating layer 130 stacked on the prepreg 110, and a circuit layer 140 formed on an outer surface of the insulating layer, but the structure of the core layer 100 used in the present invention is not limited thereto.

In addition, as shown in FIG. 1, the core layer 100 may include a via 150 connecting circuit layers formed on other layers. In the case of a single-sided printed circuit board, the core layer is configured of the insulating layer formed under the capacitor layer and the circuit layer (configured as the first circuit layer) formed on the top surface of the insulating layer.

In the printed circuit board according to the present invention, the capacitor layer 300 is stacked on the core layer 100.

At this time, the capacitor layer 300 is stacked on the core layer 100, having the inner insulating layer 200 therebetween, and is electrically connected to the first circuit layer 140 formed on the outer surface of the core layer 100.

The inner insulating layer 200 may use an insulating layer or a prepreg, similar to the core layer, and includes a via 210 so as to electrically connect the first circuit layer 140 to the capacitor layer 300.

The via 210 may be formed by filling a conductive paste in a via hole or performing plating.

At this time, the capacitor layer 300 includes the plurality of conductive projection parts 325 and 335 formed on the opposite surfaces of the upper electrode layer 320 and the lower electrode layer 330, and the dielectric layer 310 formed between the upper electrode layer 320 and the lower electrode layer 330.

It is preferable that the dielectric layer 310 uses a dielectric material having high dielectric constant so as to implement a capacitor having a high capacitance, more preferably, thinner thickness of the dielectric material and wider and higher surface area thereof. Therefore, the dielectric layer 310 may be made of plastic resin such as epoxy resin, polyimide or the like, or ceramic.

The upper electrode layer 320 and the lower electrode layer 330 are formed on both surfaces of the dielectric layer 310, wherein the conductive projection parts 325 and 335 are formed on the opposite surfaces thereof. Therefore, the conductive projection part 325 and 335 are impregnated into the dielectric layer 310.

At this time, as shown in FIG. 1, the areas of the upper electrode layer 320 and the lower electrode layer 330 are increased and the intervals between the electrode layers become narrow due to the conductive projection parts 325 and 335 formed on the opposite surfaces thereof, such that capacitance is increased. Therefore, a capacitor having high capacitance per area is formed as compared to a flat capacitor.

The conductive projection parts 325 and 335 may use a conductive material such as a metal, wherein any one or more of the conductive projection part 325 (hereinafter, upper conductive projection part) formed on the upper electrode layer 320 and the conductive projection part 335 (hereinafter, lower conductive projection part) formed on the lower electrode layer 330 may be made of a conductive paste. For example, a silver paste or a paste containing a mixture of silver and copper may be used.

In addition, any one or more of the upper conductive projection part 325 and the lower conducive projection part 335 may be configured of a plating layer integrally formed with the upper electrode layer 320 or the lower electrode layer 330. The electrode layer and the conductive projection part are integrally formed, thereby making it possible to improve adhesion between the electrode layer and the conductive projection part.

The upper conductive projection part 325 and the lower conductive projection part 335 formed, having the dielectric layer 310 therebetween, are formed to be crossed not to be in contact with each other. It is preferable that the height of the conductive projection parts 325 and 335 is smaller than the thickness of the dielectric layer 310 so that the upper conductive projection part 325 is not in contact with the lower electrode layer 330 and the lower conductive projection part 335 is not in contact with the upper electrode layer 320.

Meanwhile, the upper electrode layer 320 and the lower electrode layer 330 may be configured to include a plating layer or both a seed layer and a plating layer according to a manufacturing method, as shown in FIGS. 4 to 21.

The printed circuit board according to the present invention may further include a second circuit layer 400 formed on the dielectric layer 310 and formed on the same plane as any one or more of the upper electrode layer 320 and the lower electrode layer 330.

The capacitor layer 300 may be formed to cover the entire inner insulating layer 200 but it is preferable that the printed circuit board includes a circuit layer formed on the same plane as the capacitor layer 300 so as to control the flow of signal.

The second circuit layer 400 formed on the same plane as the electrode layers 320 and 330 may include a power circuit pattern, a signal circuit pattern, a ground circuit pattern or the like and may be formed on any one or more of the top surface and the bottom surface of the dielectric layer 310. In addition, as shown in FIG. 1, when the second circuit layers 400 are formed on both surfaces of the dielectric layer 310, they may be connected to each other through a via 410.

Meanwhile, the lower electrode layer 330 may be connected to the first circuit layer 140 formed on the core layer 100 through the via 210, and the upper electrode layer 320 may be connected to a circuit layer stacked on the upper side thereof or the second circuit layer 400 disposed on the same plane through another via.

The printed circuit board according to the present invention further includes a build-up layer 500 stacked on the capacitor layer 300, as shown in FIG. 2.

The build-up layer 500 is formed by repeating an insulating layer 510 and a circuit layer 520 and the stacked number of the build-up layer may be changed according to a purpose. When the upper electrode layer 320 and the second circuit layer 400 are formed on the same plane, the build-up layer 500 is stacked, while covering the upper electrode layer 320 of the capacitor layer 300 and the second circuit layer 400.

In addition, the printed circuit board may further include a protective layer 600 formed on the upper side of the capacitor layer 300.

When the build-up layer 500 is stacked on the capacitor layer 300 as shown in FIG. 3, the protective layer 600 is formed to cover an outer circuit layer of the build-up layer 500. However, when the build-up layer 500 is not stacked thereon, the protective layer 600 simultaneously covers the upper electrode layer 320 and the second circuit layer 400 formed on the same plane as the upper electrode layer 320.

The protective layer 600 serves to prevent the upper electrode layer 320 and the second circuit layer 400 from being oxidized. The protective layer 600 may use a solder resist which is a heat resistant resin material.

Hereinafter, a method of manufacturing a printed circuit board according to a preferred embodiment of the present invention will be described with reference to FIGS. 4 to 18.

As shown in FIG. 4, a core layer 100 having a first circuit layer 140 formed on an outer surface thereof is formed. As shown in FIG. 4, in order to form the core layer 100 including four circuit layers, a core member 110 (for example, a cured prepreg) is prepared and a plating process and a patterning process is performed thereon to form an inner circuit layer 120. And then, an insulating layer 130 is stacked on the inner circuit layer 120 and the plating process and the patterning process are performed again to form the first circuit layer 140.

At this time, in order to form a via 150 connecting the first circuit layers 140 formed on both surfaces thereof, the insulating layer 130 is stacked on the core member 110 on which the inner circuit layer 120 is formed and then a through hole is formed. And then, the outer surface of the insulating layer 130 and the inner surface of the through hole are simultaneously subjected to the plating process and then are patterned, thereby making it possible to simultaneously form the first circuit layer 140 and the via 150.

Meanwhile, the structure of the core layer 100 is merely one embodiment; however, when the insulating layer 130 is not stacked, the inner circuit layer 120 functions as the first circuit layer and the core layer 100 has a structure including the core member 110 and the circuit layers 120 formed on both surfaces thereof.

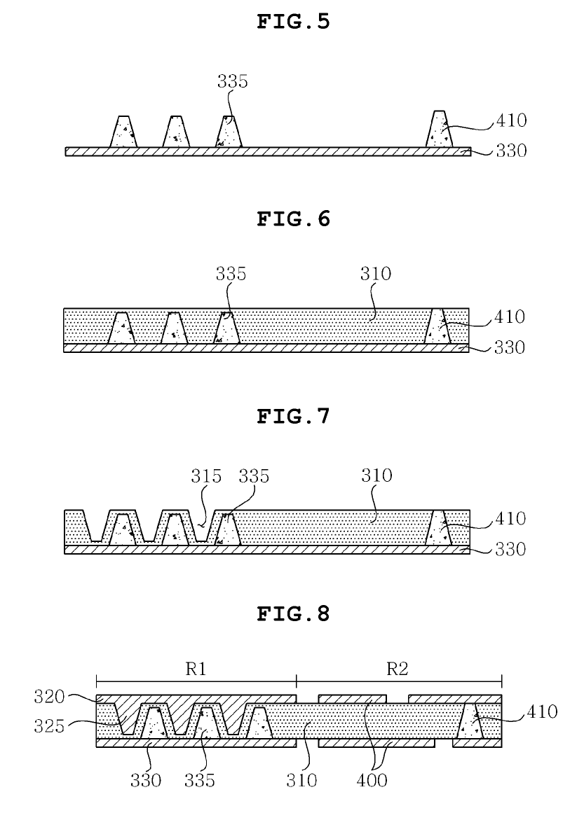

As shown in FIGS. 5 to 17, a capacitor layer 300 including a plurality of conductive projection parts 325 and 335 and a dielectric layer 310, wherein the plurality of conductive projection parts 325 and 335 are formed on the opposite surfaces of an upper electrode layer 320 and a lower electrode layer 330, and the dielectric layer 310 is formed between the upper electrode layer 320 and the lower electrode layer 330.

At this time, as shown in FIGS. 5 to 17, the forming the capacitor layer 300 may further include forming a second circuit layer 400 disposed on the same plane as the upper electrode layer 320 or the lower electrode layer 330.

In other words, the capacitor layer 300 is formed in one region R1 of the dielectric layer 310 and the second circuit layer 400 is formed in the other region R2 thereof by sharing the dielectric layer 310. At this time, the second circuit layer 400 may be formed on both surfaces of the dielectric layer 310 as shown in the figures or be formed on one surface thereof.

Hereinafter, the present embodiment will be described on the assumption that forming the second circuit layer 400 is simultaneously performed at forming the capacitor layer 300. When the conductive projection parts 325 and 335 are formed in the whole region of the dielectric layer 310 and the second circuit layer 400 is not formed, it is obvious that the process of forming the second circuit layer may be omitted. Therefore, the detailed description thereof will be omitted.

A method of manufacturing the capacitor layer will be described with reference to FIGS. 5 to 8. As shown in FIG. 5, the conductive projection parts 325 and 335 made of a conductive paste are first formed on the upper electrode layer 320 or the lower electrode layer 330 so as to form the capacitor layer 300. The capacitor layer may be formed by printing it with a mask formed with openings. Herein, a height of the conductive projection parts 325 and 335 may be controlled by the number of printing and be preferably smaller than a thickness of the dielectric layer described below.

FIGS. 5 to 8 also show a process of forming the second circuit layer 400, wherein when the second circuit layer 400 is formed on both surfaces of the dielectric layer 310, a via 410 connecting the second circuit layers 400 to be formed on both surfaces is formed by a mask printing method while simultaneously forming the conductive projection parts 335. At this time, the number of printing is controlled so that the via 410 has a higher height than the conductive projection part 335.

It is substantially determined whether or not the second circuit layer is formed at the forming the capacitor layer 300, such that the electrode layer 330 may be divided into one region R1 and the other region R2 at the forming the conductive projection part 335.

Meanwhile, for convenience of explanation, FIGS. 5 to 8 are shown based on the lower electrode layer 330. In addition, three conductive projection parts 335 are formed on the lower electrode layer 330 but it is merely one example.

Next, as shown in FIG. 6, the dielectric layer 310 is stacked on the lower electrode layer 330 so as to cover the conductive projection part 335. The dielectric layer 310 in a semi-cured state is stacked, the truncated cone shaped conductive projection part 335 is impregnated into the dielectric layer 310, and the truncated cone shaped via 410 larger than the conductive projection part 335 penetrates through the dielectric layer 310.

Thereafter, as shown in FIG. 7, a plurality of blind via holes 315 are formed in a thickness direction from the top surface of the dielectric layer 310 so as to be positioned between the conductive projection parts 335. After curing the dielectric layer 310, the blind via holes 315 may be formed by a mechanical drilling method and a laser processing method using YAG laser and Co2 laser.

As shown in FIG. 8, a plating layer is formed on the top surface of the dielectric layer 310 so that the blind via hole 315 is filled. The plating layer may be formed using an electroplating method or an electroless plating method after forming a seed layer.

At this time, when the plating layer and the lower electrode layer 330 are patterned, the plating layer formed in one region R1 becomes the upper electrode layer 320 on which the upper conductive projection part 325 is formed and the plating layer formed in the other region becomes the second circuit layer 400. The patterning is formed by performing laminating, etching, exposing, developing and etching a master film.

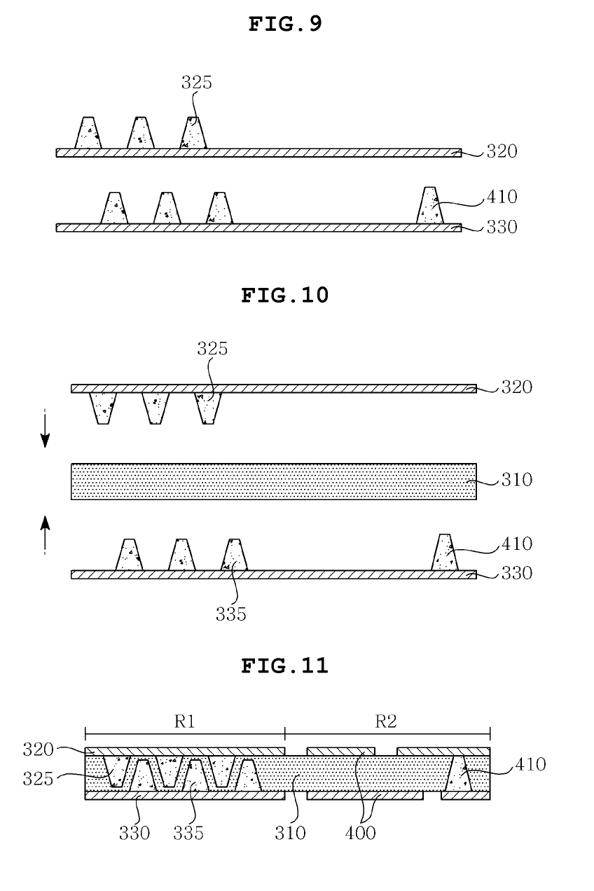

Unlike the method as shown in FIGS. 5 to 8, a method of manufacturing a capacitor layer having the conductive projection parts 325 and 335 made of a conductive paste and formed on the opposite surfaces of the upper electrode layer 320 and the lower electrode layer 330 will be described with reference to FIGS. 9 to 11. However, the detailed description of the same configuration as that described with reference to FIGS. 5 to 8 will be omitted.

First, as shown in FIG. 9, the upper conductive projection part 325 and the lower conductive projection part 335 made of a conductive paste are formed on the upper electrode layer 320 and the lower electrode layer 330, respectively. In this configuration, it is preferable that the upper conductive projection part 325 is disposed to cross the lower conductive projection part 335. This reason is to avoid contact between the upper conductive projection part 325 and the lower conductive projection part 335 when completing the capacitor layer 300.

Next, as shown in FIG. 10, the dielectric layer 310, the upper electrode layer 320, and the lower electrode layer 330 are bonded so that the conductive projection parts 325 and 335 are disposed on the opposite surfaces of the upper electrode layer 320 and the lower electrode layer 330, having the dielectric layer 310 therebetween. In this case, it is preferable that the dielectric layer 310 is in a semi-cured state. The dielectric layer 310 may be stacked on the lower electrode layer 330 and then the upper electrode layer 320 may be bonded to the dielectric layer 310, but not necessarily bonded simultaneously with each other.

In the capacitor layer 300 manufactured as described above, both the upper conductive projection part 325 and the lower conductive projection part 335 are made of a conductive paste as shown in FIG. 11.

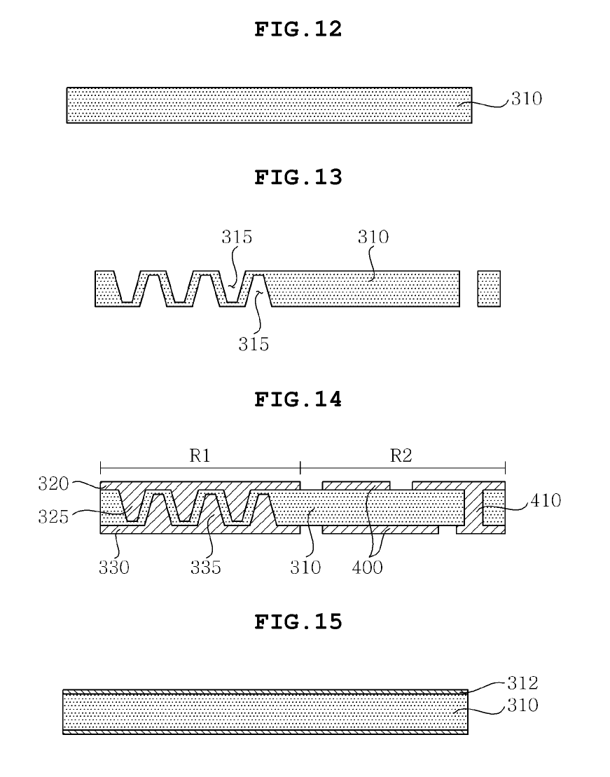

A method of manufacturing the capacitor layer 300 having a structure in which all of the conductive projection parts 325 and 335 formed on the upper electrode layer 320 and the lower electrode layer 330 are formed integrally with the electrode layers 320 and 330 will be described with reference to FIGS. 12 to 14.

First, as shown in FIG. 12, the plurality of blind via holes 315 are formed on both surfaces of the dielectric layer 310. In this case, when the blind via holes 315 formed on the top surface and the bottom surface are formed to cross each other and the second circuit layer 400 is formed on both surfaces of the dielectric layer 310, a through hole 415 may be formed in the same manner as the process of forming the blind via hole.

Next, as shown in FIG. 13, plating layers 320 and 330 are formed on the both surfaces of the dielectric layer 310 so that the blind via holes 315 are filled. The plating layers filled in the blind via holes 315 form the conductive projection parts 325 and 335.

In this case, when the through hole is also plated to form a via and patterning is performed thereon, the capacitor layer 300 and the second circuit layer 400 sharing the dielectric layer 310 are formed as shown in FIG. 14.

A method of manufacturing the capacitor layer 300 further including a seed layer and having a structure in which all of the conductive projection parts 325 and 335 formed on the upper electrode layer 320 and the lower electrode layer 330 are formed integrally with the electrode layers 320 and 330 will be described with reference to FIGS. 15 to 17.

First, as shown in FIG. 15, the plurality of blind via holes 315 are formed on both surfaces of the dielectric layer 310 having a copper foil 312 formed on both surfaces thereof. In other words, the capacitor layer 300 is formed using a copper clad laminate (CCL), wherein the copper foil 312 functions as a seed layer. In this case, when the blind via holes 315 formed on the top surface and the bottom surface are formed to cross each other and the second circuit layer 400 is formed on both surfaces of the dielectric layer 310, a through hole 415 may be formed in the same manner as the process of forming the via hole.

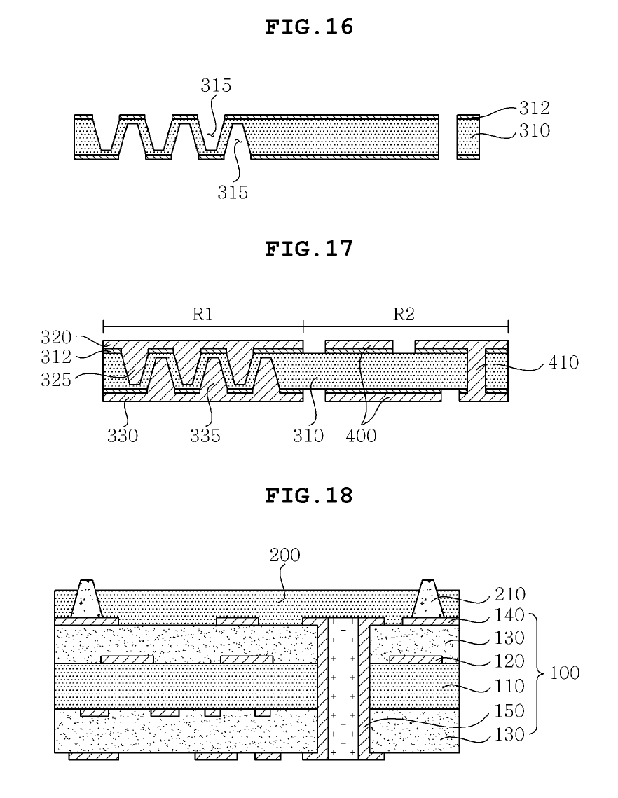

Next, as shown in FIG. 16, plating layers 320 and 330 are formed on the both surfaces of the dielectric layer 310 so that the blind via holes 315 are filled. The copper foil 312 functions as a seed layer to improve reliability of the plating layers and the plating layers filled in the blind via holes 315 to form the conductive projection parts 325 and 335.

In this case, when the through hole is also plated to form a via and a patterning is performed thereon, the capacitor layer 300 and the second circuit layer 400 sharing the dielectric layer 310 are formed as shown in FIG. 17. Therefore, the upper electrode layer 320, the lower electrode layer 330, and the second circuit layer 400 have a two-layered structure in which the plating layer is formed on the seed layer.

When the capacitor layer 300 is manufactured according to the four methods as described above, the capacitor layer 300 is stacked on the core layer 100 so that the lower electrode layer 330 is connected to the first circuit layer 140, having the inner insulating layer 200 therebetween.

First, as shown in FIG. 18, a bump is formed on the first circuit layer 140 formed on the outer surface of the core layer 100 using a conductive paste and then the inner insulating layer 200 in a semi-cured state is stacked. The bump forms a via 210. Then, a through hole may be formed after stacking the inner insulating layer 200 and the through hole may be filled with a conductive paste to form the via 210 connecting the first circuit layer 140 to the capacitor layer 300.

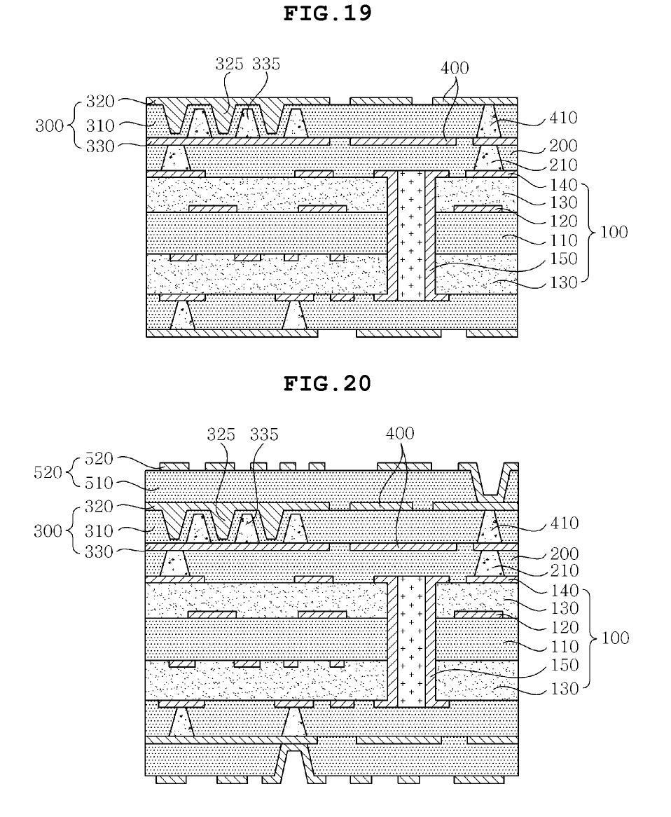

The capacitor layer 300 is stacked so that the conductive bump is connected to the lower electrode layer 330, thereby manufacturing a printed circuit board as shown in FIG. 19.

In addition, the method may further include stacking a build-up layer on the capacitor layer as shown in FIG. 20. The build-up process is performed by repeating a process of stacking the insulating layer and a process of forming the circuit layer.

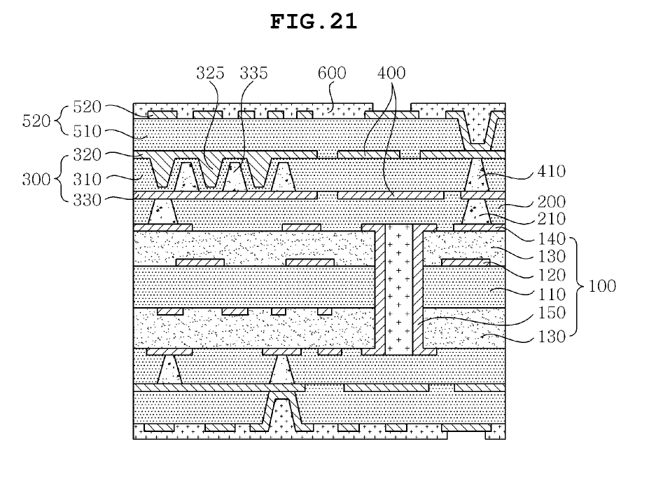

As shown in FIG. 21, the method may further include forming a protective layer 600 on the top side of the capacitor layer 300. The protective layer 600 may use a solder resist and be formed by any one of a screen printing method, a roller coating method, a curtain coating method, and a spray coating method.

In FIG. 21, the forming the protective layer is performed after the build-up process; however, when the build-up process is omitted, the protective layer 600 is formed to cover the capacitor layer 300 or both the capacitor layer 300 and the second circuit layer 400.

With the printed circuit board according to the present invention, the conductive projection parts are formed on the opposite surfaces of the two electrode layers formed, having the dielectric layer therebetween, to widen the area of the capacitor and reduce the distance between the electrodes, thereby making it possible to have an embedded high-capacitance capacitor.

In addition, the present invention can design the printed circuit board to occupy a small area but to have an embedded high-capacitance capacitor, thereby making it possible to improve freedom in design of the printed circuit board.

In addition, the printed circuit board according to the present invention forms the conductive projection parts on the electrode layer using a conductive paste, thereby making it possible to easily manufacture the high-capacitance capacitor.

Although the preferred embodiments of the present invention have been disclosed for illustrative purposes, those skilled in the art will appreciate that various modifications, additions and substitutions are possible, without departing from the scope and spirit of the invention as disclosed in the accompanying claims.

Accordingly, such modifications, additions and substitutions should also be understood to fall within the scope of the present invention.

What is claimed is:

1. A printed circuit board, comprising:
a core layer having a first circuit layer formed on an outer surface thereof; and
a capacitor layer stacked on the core layer to be electrically connected to the first circuit layer, having an inner insulating layer therebetween, and including a plurality of conductive projection parts formed on the opposite surfaces of an upper electrode layer and a lower electrode layer and a dielectric layer formed between the upper electrode layer and the lower electrode layer.

2. The printed circuit board as set forth in claim 1, further comprising:
a second circuit layer formed on the dielectric layer and formed on the same plane as any one or more of the upper electrode layer and the lower electrode layer.

3. The printed circuit board as set forth in claim 1, further comprising:
a build-up layer stacked on the capacitor layer.

4. The printed circuit board as set forth in claim 1, further comprising:
a protective layer formed on the capacitor layer.

5. The printed circuit board as set forth in claim 1, wherein any one or more of the conductive projection parts formed on the upper electrode layer and the lower electrode layer is made of a conductive paste.

6. The printed circuit board as set forth in claim 1, wherein any one or more of the conductive projection parts formed on the upper electrode layer and the lower electrode layer is a plating layer formed integrally with the upper electrode layer or the lower electrode layer.

7. A method of manufacturing a printed circuit board, comprising:
forming a core layer having a first circuit layer formed on an outer surface thereof;
forming a capacitor layer including a plurality of conductive projection parts formed on the opposite surfaces of an upper electrode layer and a lower electrode layer and a dielectric layer formed between the upper electrode layer and the lower electrode layer; and
stacking the capacitor layer on the core layer so that the lower electrode layer is connected to the first circuit layer, having an inner insulating layer therebetween.

8. The method of manufacturing a printed circuit board as set forth in claim 7, wherein the forming the capacitor layer further includes forming a second circuit layer disposed on the same plane as the upper electrode layer or the lower electrode layer.

9. The method of manufacturing a printed circuit board as set forth in claim 7, further comprising:
stacking a build-up layer on the capacitor layer.

10. The method of manufacturing a printed circuit board as set forth in claim 7, further comprising:
forming a protective layer on a top side of the capacitor layer.

11. The method of manufacturing a printed circuit board as set forth in 7, wherein the forming the capacitor layer includes:
forming conductive projection parts made of a conductive paste on any one of the upper electrode layer and the lower electrode layer;
stacking a dielectric layer on the upper electrode layer or the lower electrode layer so as to cover the conductive projection parts;
forming a plurality of blind via holes in a thickness direction from a top surface of the dielectric layer so as to be positioned between the conductive projection parts; and
forming a plating layer on a top surface of the dielectric layer so that the blind via holes are filled.

12. The method of manufacturing a printed circuit board as set forth in 7, wherein the forming the capacitor layer includes:
forming conductive projection parts made of a conductive paste on the upper electrode layer and the lower electrode layer; and
bonding the dielectric layer, the upper electrode layer, and the lower electrode layer so that the conductive projection parts are disposed on the opposite surfaces of the upper electrode layer and the lower electrode layer, having the dielectric layer therebetween.

13. The method of manufacturing a printed circuit board as set forth in 7, wherein the forming the capacitor layer includes:
forming a plurality of blind via holes on both surfaces of the dielectric layer; and
forming a plating layer on both surfaces of the dielectric layer so that the blind via holes are filled.

14. The method of manufacturing a printed circuit board as set forth in 7, wherein the forming the capacitor layer includes:
forming a plurality of blind via holes on both surfaces of the dielectric layer having copper foils formed on both surfaces thereof; and
forming a plating layer on both surfaces of the dielectric layer so that the blind via holes are filled.
